(19) United States
(12) Patent Application Publication
(10) Pub. No.: US 2020/0273712 A1
(43) Pub. Date: Aug. 27, 2020

(54) DEPOSITION PROCESSING METHOD AND PLASMA PROCESSING APPARATUS

(71) Applicant: Tokyo Electron Limited, Tokyo (JP)

(72) Inventors: Atsushi UTO, Miyagi (JP); Yoshimitsu KON, Miyagi (JP); Lifu LI, Miyagi (JP); Yuji NAGAI, Miyagi (JP)

(21) Appl. No.: 16/801,583

(22) Filed: Feb. 26, 2020

(30) Foreign Application Priority Data
Feb. 27, 2019 (JP) 2019-034841

(51) Int. Cl. H01L 21/3065; C23C 16/505; C23C 16/52; H01J 37/32; H01L 21/311; H01L 21/02

(52) U.S. Cl. CPC H01L 21/3065; C23C 16/505; C23C 16/52; H01L 21/02164; H01J 37/3244; H01L 21/31144; H01L 21/02274; H01J 37/32091

(57) ABSTRACT

A deposition processing method includes a step of depositing deposits onto a substrate using a first plasma generated in a processing condition of depositing the deposits onto the substrate, which is basically a first processing condition, and a preceding step performed before the step of depositing the deposits onto the substrate, wherein, within the step of depositing the deposits transited from the preceding step, the processing condition is controlled so as to deposit less deposits than that in the first processing condition until a state of the first plasma is stabilized.

### CROSS-REFERENCE TO RELATED APPLICATIONS

This application is based on and claims priority to Japanese Patent Application No. 2019-034841, filed on Feb. 27, 2019, the entire contents of which are incorporated herein by reference.

### BACKGROUND OF THE INVENTION

### 1. Field of the Invention

The present disclosure relates to a deposition processing method and a plasma processing apparatus.

### 2. Description of the Related Art

In etching a contact hole, there is a technique of preventing blockage of a mask opening. Patent Document 1 proposes a plasma processing method and an apparatus capable of preventing blockage of a hole when etching an oxide layer. The condition in which the blockage of the opening of the mask is prevented in order to change the processing condition so as to increase the hole size, there is a conflicting problem such that the hole size is increased or the amount of scraping at the bottom of the hole is increased.

[Patent Document 1] Japanese Unexamined Patent Publication No. 2014-090022

### SUMMARY OF THE INVENTION

The present disclosure provides a technique enabling to optimize the etched recess shape while preventing blockage of the mask opening, for example.

According to one aspect of the present disclosure, there is provided a deposition processing method including a step of depositing deposits onto a substrate using a first plasma generated in a processing condition of depositing the deposits onto the substrate, which is basically a first processing condition, and a preceding step performed before the step of depositing the deposits onto the substrate, wherein, within the step of depositing the deposits transited from the preceding step, the processing condition is controlled so as to deposit less deposits than that in the first processing condition until a state of the first plasma is stabilized.

### BRIEF DESCRIPTION OF THE DRAWINGS

FIG. 1 is a cross-sectional view illustrating an example of a plasma processing apparatus according to an embodiment.

FIGS. 2A and 2B illustrate an example of a result of a deposition process according to a comparative example.

FIGS. 3A and 3B illustrate an example of a state in which plasma is ignited in a processing condition according to an embodiment.

FIG. 4 is a view for explaining the dissociation of a gas included in a processing condition according to an embodiment.

FIG. 5 is a diagram illustrating a transient state at the time of plasma ignition according to an embodiment.

FIG. 6 illustrates an example of high frequency reflection at plasma ignition and before and after extinguishing the plasma according to the embodiment.

FIG. 7 is a flowchart illustrating an example of the plasma process according to the embodiment.

FIG. 8 is a flowchart illustrating an example of continuous plasma process according to the embodiment.

FIGS. 9A and 9B illustrates conditions for controlling the deposition amount of deposits according to the embodiment.

FIGS. 10A and 10B illustrate an example of the results of a plasma process according to the comparative example and the embodiment.

FIG. 11A to 11D illustrate an example of the results of the plasma processing according to the comparative example and the embodiment.

### DETAILED DESCRIPTION OF EMBODIMENTS

In each drawing, the same components are indicated by the same reference numerals and overlapping descriptions may be omitted.

### [Plasma Processing Apparatus]

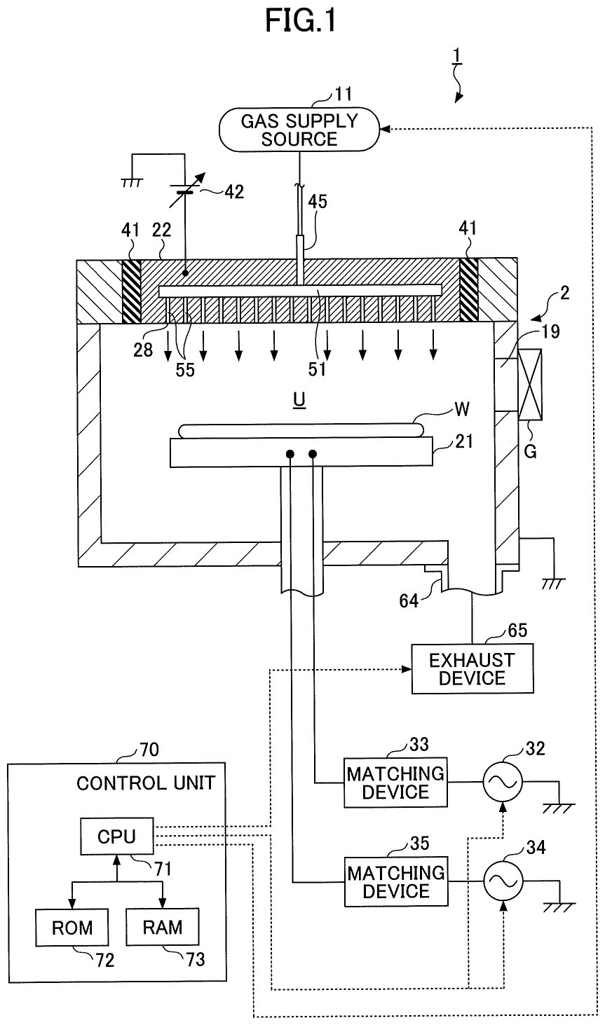

A plasma processing apparatus 1 according to the embodiment will be described with reference to FIG. 1. FIG. 1 is a cross-sectional view illustrating an example of a plasma processing apparatus 1 according to the embodiment. Here, as an example of the plasma processing apparatus 1, a capacitively coupled plasma etching apparatus will be described.

The plasma processing apparatus 1 includes a chamber 2 made of a conductive material, e.g., aluminum.

The chamber 2 is electrically grounded. The chamber 2 has a stage 21 and a showerhead 22 disposed opposite to the stage 21. The stage 21 also serves as a lower electrode so as to mount a wafer W thereon. The showerhead 22 also provides a shower of gas and serves as an upper electrode. A processing space U is formed between the stage 21 and the showerhead 22 to process the wafer W.

The stage 21 is connected to the first radio-frequency power supply 32 via a matching device 33. The stage 21 is connected to a second radio-frequency power supply 34 via a matching device 35. The first radio-frequency power supply 32 applies radio-frequency power (hereinafter referred to as “HF power”) to the stage 21 for plasma generation at a frequency of, for example, 40 to 100 MHz. The second radio-frequency power supply 34 applies radio-frequency power (also referred to as “LF power”) to the stage 21 for a bias voltage (also referred to as “LF power”) to draw ions, e.g., 3.2 MHz to 13 MHz, below 40 MHz. Although the second radio-frequency power supply 34 is for the bias voltage to draw ions, a portion of the applied LF power may also contribute to plasma generation. Also, although the first radio-frequency power supply 32 is for plasma generation, a portion of the applied HF power may also contribute to draw ions.

The matching device 33 matches the load impedance to the output impedance of the first radio-frequency power supply 32. The matching device 35 matches the load impedance to the output impedance of the second radio-frequency power supply 34. This causes the output impedance and the load impedance to be apparently identical for each of the first and second radio-frequency power supplies 32 and 34, respectively, when the plasma is being generated in the processing space U.

The showerhead 22 is mounted to the ceiling of the chamber 2 via an insulative shield ring 41 provided at its periphery. The showerhead 22 is provided with a gas inlet 45 for introducing the gas introduced from the gas supply source 11. The gas output from the gas supply source 11 is fed to the diffusion chamber 51 via the gas inlet 45 and through the gas flow passage 55 to the processing space U through the gas hole 28.

The showerhead 22 is connected to a variable DC power supply 42. The application of a negative DC voltage from the variable DC power supply 42 to the showerhead 22 draws ions into the showerhead 22 and increases the plasma density.

The bottom surface of the chamber 2 is provided with an exhaust device 65 through an exhaust port 64. The exhaust device 65 evacuates the inside of the chamber 2 to maintain a predetermined vacuum. On the side wall of the chamber 2, a gate valve G is provided, and the wafer W is carried in and out through a transfer port 19 according to the opening and closing of the gate valve G.

The plasma processing apparatus 1 is provided with a control unit 70 for entirely controlling the operation of the plasma processing apparatus. The CPU 71 of the control unit 70 performs plasma processing such as etching according to a recipe stored in a memory such as ROM 72 and RAM 73. The recipe may be set to include a process time, pressure (gas exhaust), radio-frequency power, a voltage, and flow rates of various gases, which are control information of the plasma processing apparatus 1 to a processing condition. The recipe may also be set to a temperature in the chamber (e.g., an upper electrode temperature, chamber sidewall temperature, wafer W temperature, electrostatic chuck temperature, etc.), a temperature of refrigerant output from the chiller, etc. A recipe indicating the procedures and conditions of these processes may be stored on a hard disk or a semiconductor memory. The recipe may also be set in position and read out in a portable computer-readable storage medium such as a CD-ROM, a DVD, or the like.

### [Result of Deposition Process in Comparative Example]

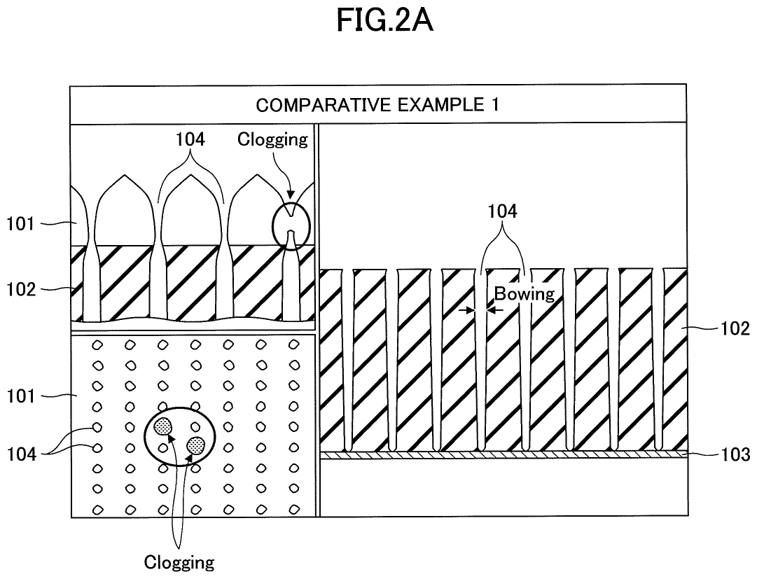

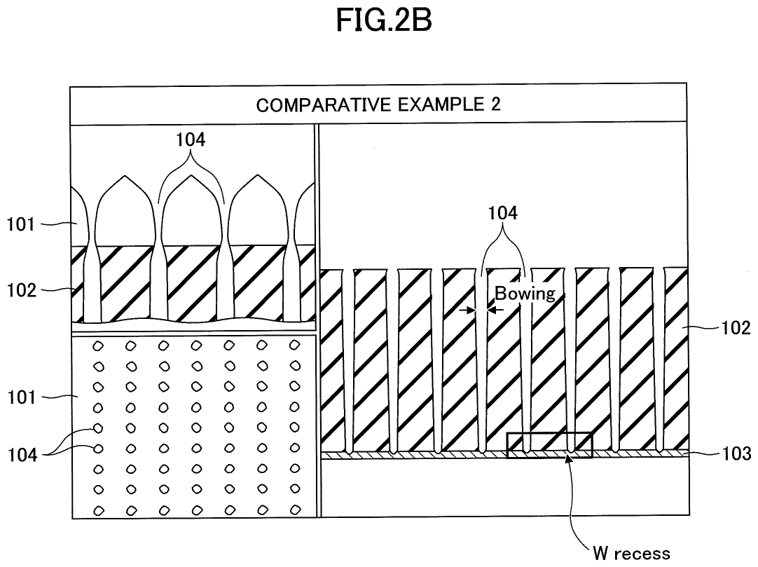

In the plasma processing apparatus 1 having such a configuration, one example of the result of generating the plasma and performing the deposition processing under the following processing condition is illustrated in FIG. 2. FIG. 2 is a diagram illustrating an example of the result of the deposition process according to Comparative Examples 1 and 2. The processing condition of Comparative Example 1 is as follows.

(Processing Condition)
Pressure 25 mT (3.33 Pa)
HF power/LF power 5000/8000 W
DC voltage −300V
Gas species C₄F₆, C₄F₈, Ar, O₂
At this time, the flow rate ratio of O₂ gas to the total flow rate of C₄F₆, C₄F₈, and O₂ gas was about 37%.

The cross-sectional view at the upper left of FIG. 2A illustrates the result of the etching process having a deposition property on the silicon oxide film 102 which is the base film of the mask 101 of the amorphous carbon based on the above-described processing condition. A cross-sectional view to the right of FIG. 2A illustrates the state of the silicon oxide film 102 after removing the mask 101 with respect to the upper left cross-sectional view of FIG. 2A. A tungsten film 103 is formed as a stop film under the silicon oxide film 102. In FIG. 2A, the bottom left illustrates the upper left cross-sectional view viewed from the upper side. With this, a portion of the hole 104 is blocked (clogged) according to the above-described processing condition.

Accordingly, in order to avoid blockage of the opening of the mask 101, the flow rate ratio of O₂ gas to the total flow rate of C₄F₆, C₄F₈, and O₂ gas was increased to approximately 39% and the etching process was performed. The other processing condition of Comparative Example 2 is the same as those of Comparative Example 1.

FIG. 2B illustrates the etching results of Comparative Example 2. In Comparative Example 2, the blockage of the aperture between the mask 101 was resolved. However, the diameter CD (Critical Dimension) of the hole 104 of the silicon oxide film 102 was widened, and the maximum width of the shape of the hole 104 formed on the silicon oxide film 102 was wider than that of Comparative Example 1. In Comparative Example 2, Bowing, in which the shape of the hole 104 becomes like a cup, is advanced than in Comparative Example 1. As the bowing of the hole 104 advances, the walls of adjacent holes 104 may come close to each other, causing the holes 104 to be in an electrically conductive state or causing poor contact.

Further, in Comparative Example 2, the amount of scraping at the bottom of the hole 104 is increased (W recess in FIG. 2B), and the etching is not completely stopped by the tungsten film 103. As described above, the processing condition is changed in a direction of increasing the size of the hole 104 in the condition of suppressing the blockage of the opening of the mask 101. Accordingly, conflicting problems may arise in that the size of the hole 104 is increased or the amount of scraping at the bottom of the hole 104 is increased.

Accordingly, we propose a method in which the etched recess shape can be optimized in the plasma process including the deposition process according to one embodiment described below while preventing the blockage of the opening of the mask.

### [Time of Plasma Ignition]

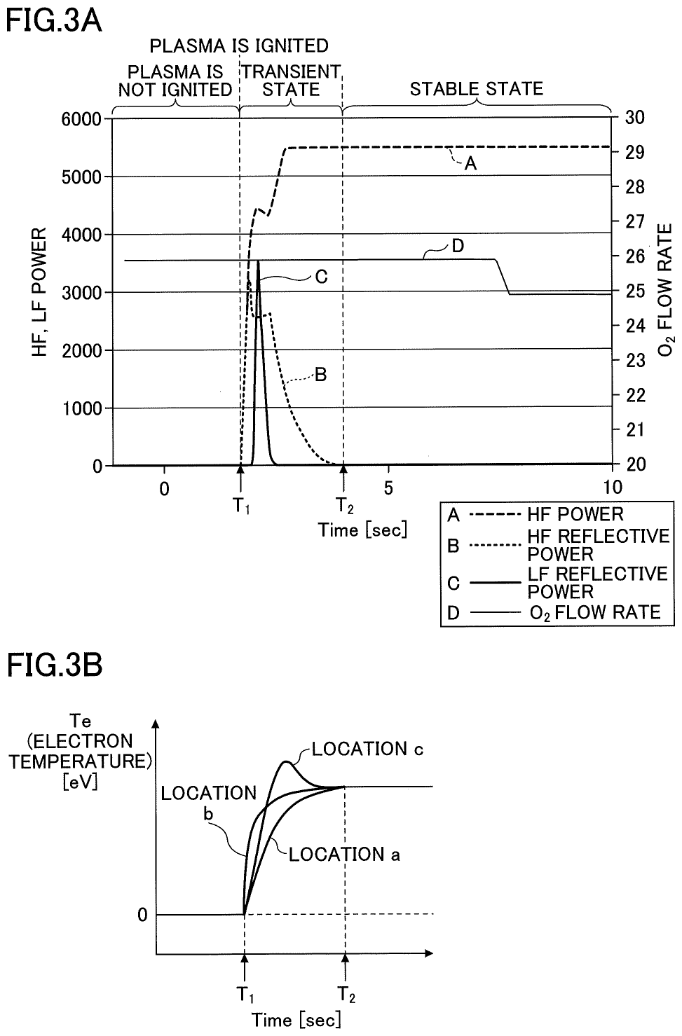

Referring to FIGS. 3A and 3B, the transient and stable state of the plasma state at the time of plasma ignition are described and the blockage of the opening of the mask is discussed. The horizontal axis of the graph in FIG. 3A represents time, and the vertical axis represents HF power or LF power (including reflected power). The time to time T1 is when the plasma is not ignited.

After plasma ignition, a process of depositing deposits onto a wafer W by etching (also referred to as a “first etching step”) is performed using first plasma generated based on the first processing condition, which will be described later. Prior to the plasma ignition, it is a pre-process that is performed prior to the first etching step.

After time T1 when the plasma ignites, the plasma is in a transient state between time T1 and time T2 until the plasma is in a stable state. The plasma state changes from moment to moment, and the plasma becomes in a stable state.

A in the graph is the HF power applied to the stage 21 from the first radio-frequency power supply 32. B is the HF reflective power reflected from the first radio-frequency power supply 32 without being used to generate the plasma. C is LF-reflected power reflected from the second radio-frequency power supply 34 toward the second radio-frequency power supply 34 without being used for plasma generation (drawing ions) out of the LF power applied to the stage 21. The HF reflective power and the LF reflective power are monitored by a sensor that detects the reflective power. It is also applied from the second radio-frequency power supply 34 to the stage 21 as LF power, although not illustrated. Additionally, although not illustrated, a negative DC voltage is applied from the variable DC power supply 42 to the showerhead 22.

In other words, the difference between the HF power indicated by A and the HF reflected power indicated by B corresponds to the HF power actually used to generate the plasma. In addition, the difference between the LF power (not illustrated) and the LF reflective power (denoted by C) is actually the LF power actually used for the plasma generation (drawing ions).

Accordingly, the plasma state may have changed both locally and temporally during a transient state in which the HF reflective power illustrated in B and/or the LF reflective power illustrated in C is generated (between time T1 and time T2), as illustrated in FIG. 3(b). In other words, in the transient state, the plasma formation is unstable, the plasma density and the plasma electron temperature are locally high or low, and the plasma state changes spatially throughout and locally in the process space U. For example, the plasma electron temperature Te differs in locations a-c of the processing space U, and the electron temperature Te of plasma varies temporally in each location a to c.

In other words, after the time T2 when both the HF reflective power and the LF reflective power become 0 (W), the plasma can be determined to be in a stable state.

However, this is not limited thereto, and it may be determined that the plasma is stable when both the HF reflective power and the LF reflective power fall below a predetermined value.

In the embodiment illustrated in FIGS. 3A and 3B, the HF power is applied at the timing of the time T1 and the LF power is applied 0.2 seconds later to ensure that the plasma ignites and to suppress the generation of particles in the processing space U. The DC voltage is also applied 0.2 seconds after the LF power is applied. However, the present embodiment is not limited thereto. A simultaneous application may be performed, and the interval may be about 1 to 2 seconds. In addition, the order may be changed such as applying the HF power after the LF power is applied first.

In addition, the effective values of HF power, LF power, and DC voltage may be applied in stages.

Additionally, besides HF power, LF power, DC voltage, other device parameters associated with plasma generation may be varied even if the contribution is low. In any case, the application, etc. is terminated between times T1 and T2 until the plasma stabilizes.

After the plasma is ignited in FIG. 3, the process of depositing deposits with respect to the wafer W is performed using a first plasma generated under the first processing condition when the plasma is stabilized. The first processing condition is as follows.

(First Processing Condition)
Pressure 25 mT (3.33 Pa)
HF power/LF power 5000/8000 W
DC voltage −300V
Gas species C₄F₆, C₄F₈, Ar, O₂
In this step, a silicon oxide film 102 is etched into the opening of the mask 101 until the tungsten film 103 is exposed.

At this time, etching is promoted mainly by the CF-based gas (C₄F₆, C₄F₈), and a hole 104 is formed in the silicon oxide film 102. In addition, during the etching process, deposits containing mainly carbon adhere to the upper surface, the side surfaces of the mask 101, the side surfaces of the hole, or the like, so that the selective ratio of the mask can be secured, and verticality of the hole 104 shape can be ensured.

An example of a pre-process performed prior to the deposition process is the step in FIG. 3A at a time when the plasma is not ignited to produce the plasma. In the pre-process, the first processing condition is set to a second processing condition in which HF power, LF power, and DC voltage are not applied.

The flow rate of the gas is described later.

In the plasma processing according to this embodiment, when moving from the pre-process to the deposition process, a transient state immediately after the plasma ignition, that is, a condition in which deposits are not deposited on the wafer W rather than the first processing condition until the state of the first plasma is stabilized, is controlled.

As an example of this processing condition, as illustrated in FIG. 3D, the flow rate of O₂ gas is increased to increase the flow rate ratio of O₂ gas to the other CF system gas among the gas species of the first processing condition. When O₂ gas is increased, C of a CF-based gas such as C₄F₆ or C₄F₈ reacts with O to form CO or CO₂, which volatilizes. This allows the amount of deposition during the transition from the pre-process to the deposition process to be reduced compared to the amount deposited in the stable state. The increase in the flow rate of O₂ gas may be increased from the time of the second processing condition of the pre-process or may be increased immediately after plasma ignition, as illustrated in D of FIG. 3. Alternatively, the flow rate of an inert gas, such as Ar gas, which induces plasma ignition may be increased. If the plasma state is not destabilized again due to the introduction of the CF system gas when a transition is made from a transient state to a stable state, the gas in the second processing condition and the transient state may only be an inert gas.

The timing for increasing the flow rate of the O₂ gas may be any time (a time 0 to T1 of FIGS. 3A and 3B) at which the pre-process is performed, or it may be at the time of plasma ignition (the time T1) or a predetermined time before the time T1. The flow rate of the O₂ gas returns to the original flow rate after a predetermined period of time after entering into the stable state. The flow rate of the O₂ gas may be controlled to the original flow rate immediately after it enters a stable state.

Thus, the HF power and LF power are overshot or undershot during starting up the plasma and are not stable. When starting up the plasma, the radical state of the gas is easily changed. Each radical also has a different lifetime. Thus, the reflected state of the HF power and LF power may change, or the plasma density may be higher or lower overall and locally in the processing space U.

Thus, the opening of the mask 101 is prone to blockage, and variations may occur in size depending on the location of the opening of the mask 101.

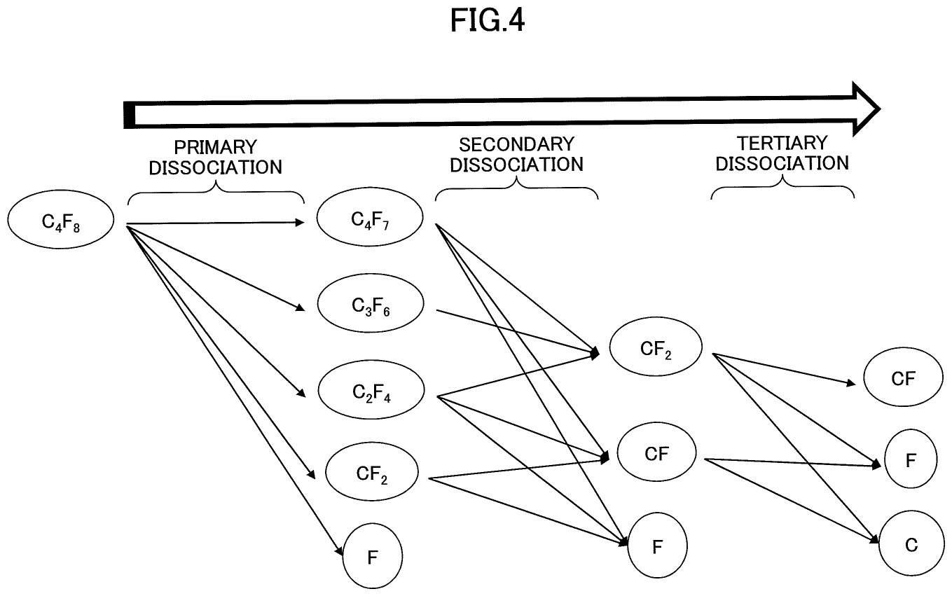

For example, an example of a dissociation pattern of the C₄F₈ gas is illustrated in FIG. 4. The horizontal axis illustrates the number of dissociations from left to right. Although the life span of each radical after its dissociation is illustrated in the same way, in practice the life span of each radical is different.

The C₄F₈ gas changes to the radical states of C₄F₇, C₃F₆, C₂F₄, CF₂, and F upon primary dissociation after plasma ignition. Secondary dissociation and tertiary dissociation occur within a short period of time. For example, C₂F₄, in its primary dissociation from the C₄F₈ gas, dissociates again to the radical states of CF₂, CF, and F. This dissociation pattern is due to the plasma electron temperature Te. Thus, in the transient state immediately after plasma ignition illustrated in FIG. 3B, the C₄F₈ gas changes to a variety of radical states in a short time, and the type and deposition location of the deposited precursor varies.

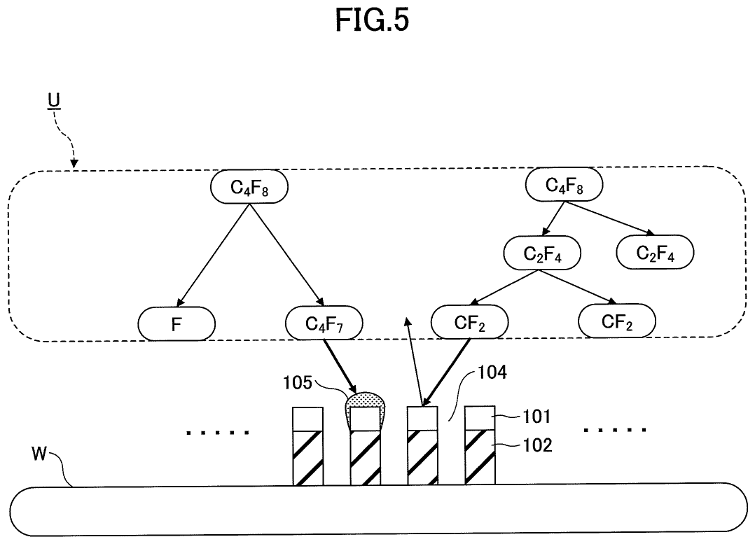

As an example illustrated in FIG. 5, C₄F₇ with primary dissociation from the C₄F₈ gas has a higher ratio of C to F than C₄F₈, so that the deposition amount is higher than C₄F₈ and the adhesion coefficient is higher than that of CF₂ with secondary dissociation from the C₄F₈ gas. Accordingly, deposits 105 composed of precursors or the like of C₄F₇ adhere to and deposit on the mask 101, causing the mask 101 to become occluded when the deposited amount is high.

On the other hand, since the adhesion coefficient of CF₂ in the state of secondary dissociation from the C₄F₈ gas is lower than that of C₄F₇ or the like, it is desorbed and not deposited even if it is deposited on the mask 101. Thus, in the transient state, precursors are unevenly fed onto the mask 101, causing deposits 105 to deposit in an uneven shape with respect to the mask 101. However, FIG. 5 is a brief description of an example of a state for easy explanation, and the transient state changes every minute so as not to be limited to this case.

Accordingly, in the deposition process of the plasma process in accordance with the present embodiment, the plasma is controlled in a temporally and spatially unstable transient state so that deposits are not deposited more than in the first processing condition. This prevents local blockage of the mask opening due to locally high plasma density during the period of transients. As described above, the blockage of the mask 101 is likely to occur when the plasma is unstable. Therefore, the processing condition are limited to the transient state and adjusted to a “condition in which no deposits are deposited” rather than the first processing condition. Accordingly, the verticality of the hole 104 of the silicon oxide film 102 can be secured while avoiding the blockage of the opening of the mask, and the amount of shaving at the bottom of the hole 104 can be suppressed, thereby optimizing the shape of the hole 104.

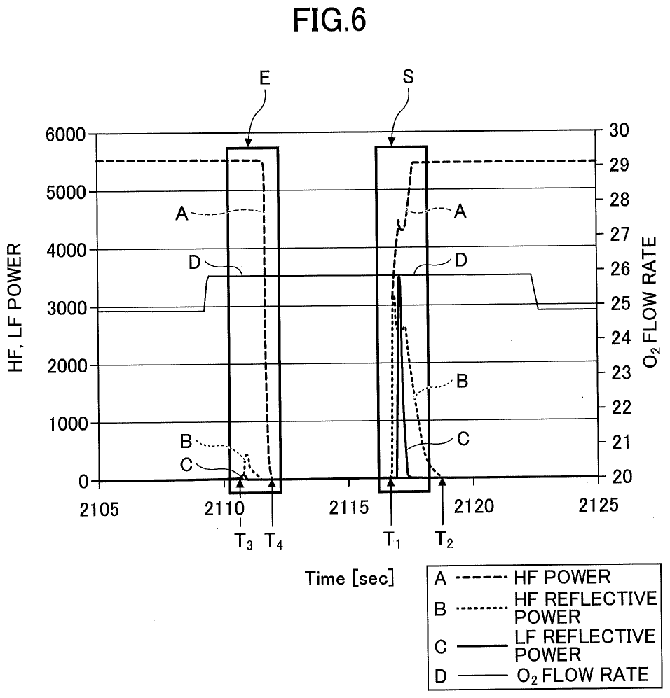

Further referring to FIG. 6, the S frame of FIG. 6 illustrates a state of plasma instability where the HF reflective power and the LF reflective power are generated at the time of plasma ignition, as described in FIG. 3. On the other hand, the E frame of FIG. 6 illustrates that the plasma is in an unstable state with HF reflective power and LF reflective power generated when the plasma extinguishes the fire. For example, if the DC voltage from the variable DC power supply 42 is turned off to T3 about 2 seconds before the time T4 at which the HF power and LF power are turned off to suppress particle generation in the process space U even when the plasma is extinguished, the plasma state in the chamber 2 will change. Accordingly, even in the condition inside the E-frame at the time of plasma extinguishing, the processing condition is limited to the transient condition and adjusted to the “condition in which no deposits are deposited”.

That is, in the step of depositing deposits to the wafer W using the first plasma generated based on the first processing condition, when the state of the first plasma illustrated in E in FIG. 6 is stopped, the condition in which deposits are not deposited to the wafer W is controlled rather than the first processing condition. The timing of the control is from a time T3, a predetermined time prior to a time T4 at which the state of the first plasma is stopped until the state of the first plasma is stopped.

This controls the conditions in which the plasma does not deposit deposits in a temporal and spatially unstable transient state, not only at rise of the plasma illustrated in S, but also at decay of the plasma illustrated in E. This prevents local blockage of the mask opening due to locally high plasma density during the period of transient state.

In the embodiment illustrated in FIG. 6, after the DC voltage is turned off at the time of extinguishing the plasma, the HF power and the LF power are simultaneously turned off. However, this is not limited thereto, and the order may be changed. In any case, if a plasma causes an unstable transient state, it is desirable to adjust the processing condition to “a condition that does not deposit deposits”.

Also, after the plasma is extinguished, the amount of radicals produced attenuates. However, since the life of each radical varies, the type of precursor and the location of deposits remaining during the attenuation varies and varies over time. Therefore, it is desirable to adjust the processing conditions just before extinguishing the plasma to “conditions that do not deposit deposits”.

In the plasma rise, plasma decay, and continuous plasma process described below, the timing of increasing the O₂ gas is when or before the plasma state changes. An example of changing the plasma condition is when the HF power is changed to be switched on or off or made high or low, when the LF power is changed to be switched on or off or made high or low, when the DC voltage is switched on or off, or when the gas is changed. For example, the timing of supplying the O₂ gas during the plasma is decaying is preferably the time of extinguishing the plasma, i.e., a time T3 a predetermined time earlier than the time T4 when stops the state of the first plasma of FIG. 6 or a time earlier than the time T3.

### [Plasma Processing Including the Deposition Process]

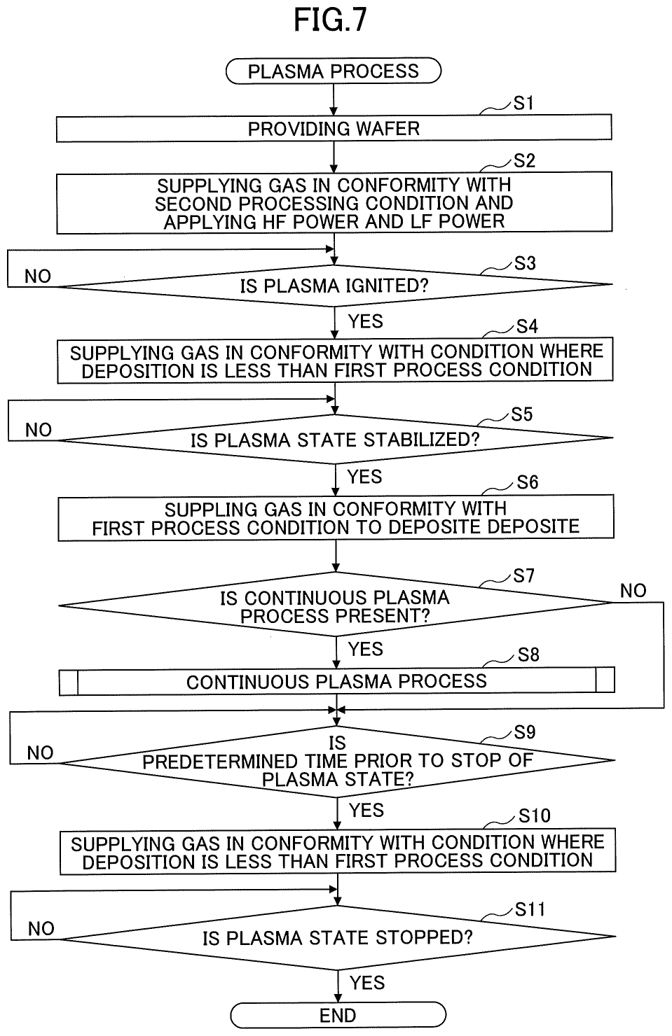

Next, an example of the plasma process that includes the deposition step according to an embodiment will be described with reference to FIG. 7. FIG. 7 is a flowchart illustrating the example of the plasma process according to the embodiment. The process is controlled by the control unit 70.

When this process is started, the control unit 70 first provides a wafer W. Specifically, the control unit 70 opens the gate valve G, inserts a transfer arm (not illustrated) from the transfer port 19 into the chamber 2, and places the wafer W on the stage 21 (step S1).

Next, the control unit 70 supplies a gas according to the second processing condition and applies the HF power and LF power (step S2). Next, in step S3, the control unit 70 determines whether the plasma is ignited. The control unit 70 can determine whether the plasma has ignited from the measurement result of the luminescence intensity of the plasma. However, this is not limited thereto, and the control unit 70 may use other measurement methods that are capable of determining whether the plasma has ignited.

When the control unit 70 waits for the determination that the plasma is ignited and determines that the plasma has been ignited, the control unit 70 supplies the gas according to a condition having an inferior deposition property to that in the first processing condition (step S4).

Next, the control unit 70 determines whether the plasma state is stable (step S5). The control unit 70 waits until the plasma state is determined to be stable, and when the plasma state is determined to be stable, the gas is supplied according to the first processing condition, an etching process is performed, and deposits the deposits are deposited (step S6).

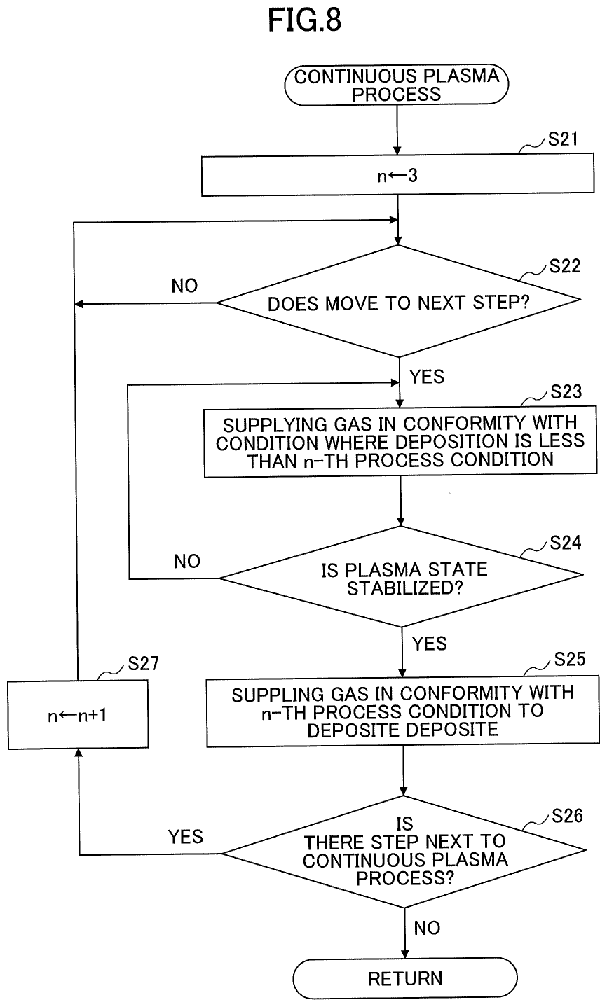

Next, in step S7, the control unit 70 determines whether there is the continuous plasma process. The continuous plasma process is the plasma process that transfers the plasma from one step of the etching to the next step without extinguishing the plasma. At each transition, the gas is switched according to each step. When this continuous plasma process is determined to be present, the control unit 70 performs the continuous plasma process of step S8. The continuous plasma process is described below with reference to the flowchart of FIG. 8.

In step S7, when it is determined that there is no continuous plasma process, the control unit 70 determines whether it is before a predetermined time after stopping the plasma state (step S9). The control unit 70 waits until a predetermined period of time before the plasma state is stopped, and when the plasma state is determined to be stopped, the control unit 70 supplies the gas according to a condition having an inferior deposition property to that in the first processing condition (step S10).

Next, in step S11, the control unit 70 determines whether to execute the stopping of the plasma state. The control unit 70 waits until the plasma state is determined to be stopped, and when the plasma state is determined to be stopped, the supplies of the HF power and LF power are stopped. Thus, this process ends.

### [Continuous Plasma Process]

The continuous plasma process invoked in step S8 of FIG. 7 will be described with reference to FIG. 8.

FIG. 8 is a flowchart illustrating an example of the continuous plasma process according to the embodiment.

In the continuous plasma process, the control unit 70 sets the variable n to 3 (step S21) and determines whether to proceed to the next step (step S22). When the control unit 70 waits for a time to transit to the next step, and then the process is determined to transit to the next step, the control unit 70 supplies the gas according to the condition having an inferior deposition property to that in the n processing condition (here, the third processing condition), which is the processing condition of the next step (step S23).

Next, in step S24, the control unit 70 determines whether the plasma state is stable. The control unit 70 repeats the process of step S23 and step S24 until it is determined that the plasma state becomes stable. When it is determined that the state of the plasma is stable, the control unit 70 supplies a gas according to an n-th processing condition, performs an etching process of the next step, and deposits the deposits (step S25).

Next, the control unit 70 determines whether there is the next step (process) of continuous plasma process (step S26). When it is determined that there is no subsequent step of the continuous plasma process, the control unit 70 ends this process. When it is determined that there is the next step of the continuous plasma process, the control unit 70 adds 1 to the variable n (step S27) and returns to step S22 to perform the process in steps S22 to S27 for the next step of the continuous plasma process. The processes of steps S22 to S27 are repeated until it is determined in step S26 that there is no subsequent step of the continuous plasma process.

According to this, for example, when switching from step A to step B and the process in which the gas is changed by the continuous plasma process, a process of increasing the O₂ gas is performed at the end of step A or at the beginning of step B, for example, for about a few seconds in step S23.

This adjusts the processing conditions to “conditions that do not deposit deposits” when switching the continuous plasma process that changes the plasma condition, as well as when igniting the plasma and extinguishing the plasma. That is, at the time of switching the step of continuous plasma process, the gas species, F-power, etc. are changed to control the condition in which deposits are not deposited in a transient state in which the plasma becomes temporally and spatially unstable. This prevents localized blockage of the mask opening due to locally high plasma density. Also, in the next step of the stable state, the n-th processing condition allows deposits to be deposited from a condition that does not cause deposits to be deposited on the wafer W. Accordingly, the blockage of the mask opening can be prevented while avoiding Bowing in the hole 104 or the amount of scraping at the bottom of the hole 104 from being large.

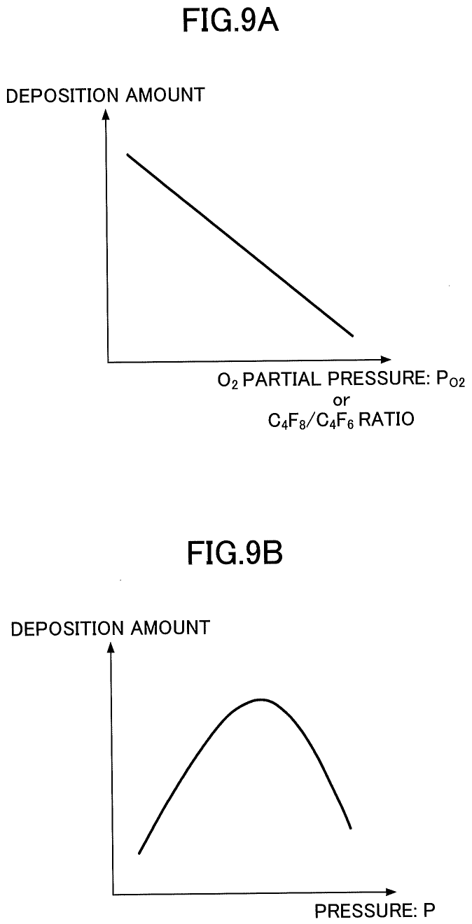

An example of a method of adjusting a processing condition to “a condition in which deposits are not deposited” will be described with reference to FIGS. 9A and 9B. FIGS. 9 A and 9B illustrate the condition for controlling the deposition amount of the deposits according to the embodiment. FIG. 9A is a graph illustrating an example of deposition for the partial pressure P_{O2} of O₂ gas for the entire gas, or deposition for the flow ratio of C₄F₈/C₄F₆. FIG. 9B is a graph illustrating an example of the amount of deposits deposited for the pressure P in the chamber.

As illustrated in FIG. 9A, increasing the ratio of a C₄F₈ gas relative to a C₄F₆ gas can reduce a ratio of a precursor having a deposition property or increase a ratio of a precursor having a reactive property. Also, by increasing the partial pressure P_{O2} of the O₂ gas relative to the total gas, the precursor having the deposition property can be removed.

Also, as illustrated in FIG. 9B, by controlling the pressure P in the chamber, it is possible to reduce the percentage of the precursor having the deposition property, increase the percentage of the precursor having the reactive property, or remove the precursor having the deposition property. However, O₂ gas and another processing condition need to be adjusted so that the plasma condition do not change significantly.

### [Results]

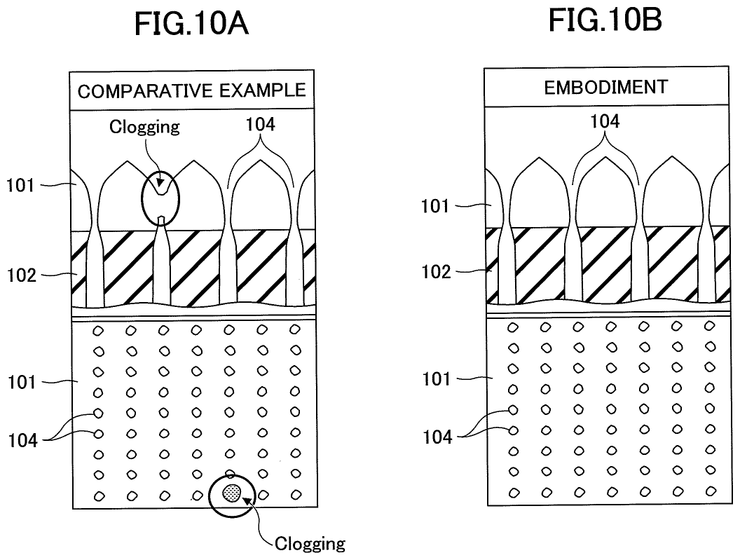

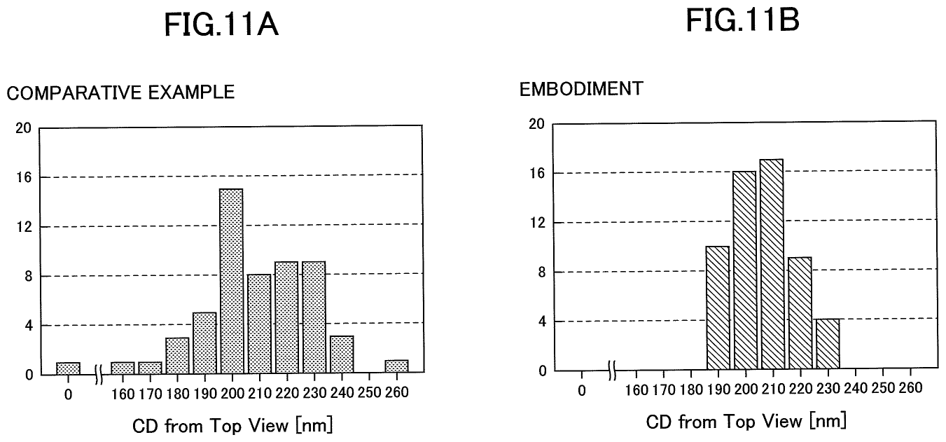

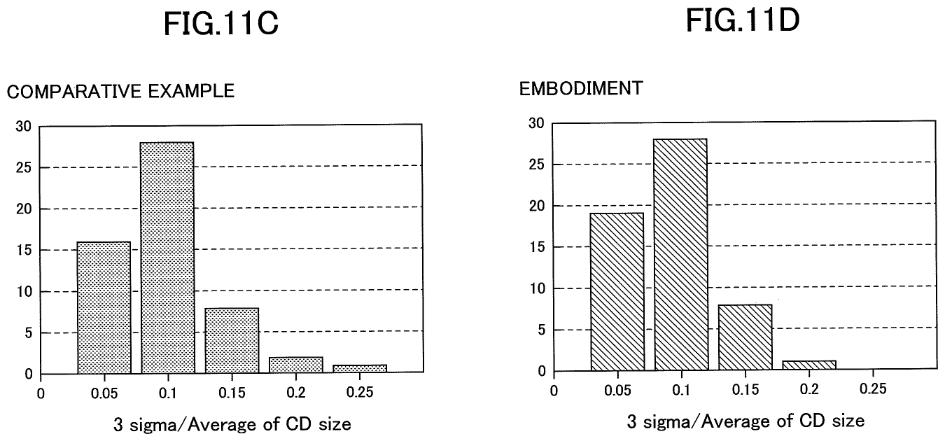

Finally, an example of the results of plasma processing according to the embodiment will be described with reference to FIGS. 10A to 11D. FIGS. 10A and 10B are a cross-sectional and plan view illustrating an example of the results of a plasma process according to an embodiment. FIGS. 11A to 11D illustrate a frequency distribution (histogram) representing a variation in the size of the CD of holes 104 (56) and the roundness of holes 104 that can be measured from the plan view of the etching shape as a result of plasma processing according to the embodiment.

In the plasma process of this embodiment, the supply of O₂ gas is increased or the supply of O₂ gas is initiated during the unstable transient state of the plasma state. In the comparative example, the supply of O₂ gas is not increased or the supply of O₂ gas is not initiated during the unstable transient state of the plasma state. Therefore, as illustrated in FIG. 10B, in this embodiment, the opening of the mask 101 was not blocked (clogged) compared to the comparative example of FIG. 10A.

In this embodiment, as illustrated in FIG. 11B, the variation of the CD of the hole 104 is reduced compared to the comparative example illustrated in FIG. 11A. Further, as illustrated in FIG. 11D, in this embodiment, the roundness of the hole 104 is closer to “0” compared to the comparative example of FIG. 11C.

In the calculation for obtaining the result in FIG. 11, the dimension was measured by the opposing angle of the opening of each hole from an SEM image of the opening of each hole, and the average value of the dimension was defined as the dimension (the size of the CD) of each hole. The ratio of the deviation (3σ) to the average value was used as the roundness.

[Method for Determining that the Plasma is Stable]

An example of a method for determining “plasma is stable” is to determine that the plasma is stable when the reflected waves of HF power and the reflected waves of LF power disappear or fall below a predetermined value. However, the method of determining that the plasma is stable is not limited thereto. The following various methods of determination can be used.

When the matching position of the matching devices 33 and 35 is the same as the pre-stored plasma stabilization position or is within the specified range.

When the measured plasma monitor value is the same as the stored plasma stabilization value or falls within the specified range when a plasma monitoring device using an emission spectrometer (OES), such as an endpoint detection device, is installed in the plasma processing apparatus 1.

When a high-frequency (RF) voltage/current/phase monitoring device for energizing an electrode such as a VI sensor capable of measuring a voltage value or a current value is installed, or when the respective monitoring values by the apparatus are the same as the plasma stabilization value stored in advance, or when the value is within the specified range. In addition to the methods described above, a method of monitoring HF power, LF power, and plasma states may be used.

As described above, according to the plasm processing of this embodiment, a recess at the bottom of the hole or the Bowing in the etching shape can be prevented while avoiding blockage of the opening of the mask.

The deposition processing method and plasma processing apparatus according to one embodiment disclosed herein are to be considered exemplary in all respects and not limiting. The above embodiments may be modified and altered in various forms without departing from the appended claims and spirit thereof. The matters described in the above embodiments may take other configurations to the extent not inconsistent, and may be combined to the extent not inconsistent.

The disclosed plasma processing apparatus is applicable to any type of ALD (Atomic Layer Deposition), Capacitively Coupled Plasma (CCP), Inductively Coupled Plasma (ICP), Radial Line Slot Antenna, Electron Cyclotron Resonance Plasma (ECR), and Helicon Wave Plasma (HWP).

### EXPLANATION OF SYMBOLS

1: Plasma processing apparatus
2: Chamber
21: Stage
22: Showerhead
32: First radio-frequency power supply
34: Second radio-frequency power supply
42: Variable DC power supply
70: Control unit
101: Mask
102: Silicone oxide film
103: Tungsten film
104: Hole

### Effect of the Invention

According to one aspect, a deposition processing method and plasma processing apparatus are provided which can optimize the etched recess shape while preventing blockage of the mask opening.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments.

Although the deposition processing method has been described in detail, it should be understood that the various changes, substitutions, and alterations could be made hereto without departing from the spirit and scope of the invention.

What is claimed is:

1. A deposition processing method comprising:
a step of depositing deposits onto a substrate using a first plasma generated in a processing condition of depositing the deposits onto the substrate, which is basically a first processing condition; and
a preceding step performed before the step of depositing the deposits onto the substrate,
wherein, within the step of depositing the deposits transited from the preceding step, the processing condition is controlled so as to deposit less deposits than that in the first processing condition until a state of the first plasma is stabilized.

2. The deposition processing method according to claim 1,
wherein the preceding step is performed based on a second processing condition, and
wherein the second processing condition differs from the first processing condition.

3. The deposition processing method according to claim 2,
wherein plasma is not generated in the preceding step.

4. The deposition processing method according to claim 2,
wherein, in the step of depositing the deposits onto the substrate using an n-th plasma generated based on an n-th processing condition (n≥3) different from the first processing condition,
wherein, in a case where the step of depositing using the first plasma transits to a step of depositing using the n-th plasma, the step of depositing using the first plasma is controlled to be the processing condition in which the deposits are not deposited onto the substrate less than that in the n-th processing condition until a state of the n-th plasma is stabilized.

5. The deposition processing method according to claim 1,
wherein a value indicative of the processing condition of an n-th plasma (n=1 or n≥3) is controlled so that the deposits are not deposited on the substrate more than that in an n-th processing condition corresponding to the n-th plasma until the value is within a predetermined normal range.

6. The deposition processing method according to claim 1,
wherein the processing condition of depositing the deposits onto the substrate less than the deposits in an n-th processing condition (n=1 or n≥3) is to use a gas for removing a precursor having a deposition property.

7. The deposition processing method according to claim 1,
wherein the condition of depositing the deposits onto the substrate less than the deposits in an n-th processing condition (n=1 or n≥3) is to use a gas of reducing a ratio of a precursor having a deposition property lower than that in a gas used in an n-th processing condition and/or a gas of increasing a ratio of a precursor having a reactive property higher than that in a gas used in the first processing condition.

8. A deposition processing method comprising:
a step of depositing deposits onto a substrate using a first plasma generated in a processing condition of depositing the deposits onto the substrate, which is basically a first processing condition; and
a preceding step performed before the step of depositing the deposits onto the substrate,
wherein, within the step of depositing the deposits to stop a state of the first plasma, the processing condition is controlled so as to deposit less deposits than that in the first processing condition until the state of the first plasma is stopped from a time earlier than a time of stopping the state of the first plasma by a predetermined time period.

9. The deposition processing method according to claim 8,
wherein a value indicative of the processing condition of an n-th plasma (n=1 or n≥3) is controlled so that the deposits are not deposited on the substrate more than that in an n-th processing condition corresponding to the n-th plasma until the value is within a predetermined normal range.

10. The deposition processing method according to claim 8,
wherein the processing condition of depositing the deposits onto the substrate less than the deposits in an n-th processing condition (n=1 or n≥3) is to use a gas for removing a precursor having a deposition property.

11. The deposition processing method according to claim 8,
wherein the condition of depositing the deposits onto the substrate less than the deposits in an n-th processing condition (n=1 or n≥3) is to use a gas of reducing a ratio of a precursor having a deposition property lower than that in a gas used in an n-th processing condition and/or a gas of increasing a ratio of a precursor having a reactive property higher than that in a gas used in the first processing condition.

12. A plasma processing apparatus comprising:
a chamber; and
a control unit, the control unit
providing a substrate in the chamber,
depositing deposits onto the substrate using a first plasma generated based on a first processing condition, and
controlling, within the depositing the deposits transited from a preceding step performed before the depositing, a processing condition so as to deposit less deposits than that in the first processing condition until a state of the first plasma is stabilized.

13. A plasma processing apparatus comprising:
a chamber; and
a control unit, the control unit
providing a substrate in the chamber, and
depositing onto the substrate using a first plasma generated based on a first processing condition, and
controlling, within the depositing the deposits transited from a preceding step performed before the depositing, a processing condition so as to deposit less deposits than that in the first processing condition until the state of the first plasma is stopped from a time earlier than a time of stopping the state of the first plasma by a predetermined time period.
